(19) United States
(12) Patent Application Publication
(10) Pub. No.: US 2004/0060505 A1
(43) Pub. Date: Apr. 1, 2004

(54) Substrate processing apparatus and substrate processing method

(75) Inventors: Shuzo Nagami, Kyoto (JP); Kazunori Fujikawa, Kyoto (JP); Hidehiko Ozaki, Kyoto (JP)

Correspondence Address: OSTROLENK FABER GERB & SOFFEN, 1180 AVENUE OF THE AMERICAS, NEW YORK, NY, 100368403

(73) Assignee: Dainippon Screen Mfg. Co., Ltd.

(21) Appl. No.: 10/671,817

(22) Filed: Sep. 26, 2003

(30) Foreign Application Priority Data
Sep. 26, 2002 (JP) 2002-280643
Jul. 29, 2003 (JP) 2003-202882

(51) Int. Cl. C30B 1/00

(52) U.S. Cl. 117/200

(57) ABSTRACT

A substrate processing apparatus for drying a substrate is provided with a chamber, quartz tank, nitrogen supply part, blowing mechanism, hot water unit and substrate holding mechanism. A substrate after being subjected to cleaning with pure water is placed in the quartz tank in the chamber. This substrate is heated by immersing it into hot water supplied from the hot water unit (degassed and heated pure water), and then lifted in the atmosphere of the chamber by the substrate holding mechanism. The atmosphere of the chamber is brought into a low oxygen state by using of nitrogen gas supplied from the nitrogen supply part and blowing mechanism. Thereby, the pure water attached to the substrate evaporates by the accumulated heat of the substrate in the low oxygen atmosphere. This permits to provide a substrate processing apparatus and a substrate processing method with which it is possible to dry a substrate while suppressing the occurrence of water marks.

### BACKGROUND OF THE INVENTION

1. Field of the Invention

The present invention relates to a technique of drying a processing liquid attached to a semiconductor substrate or a substrate for liquid crystal (hereinafter referred to simply as a “substrate”) after its cleaning process in its manufacturing steps.

2. Description of the Background Art

In the manufacturing steps of a substrate, for example, exposure and development process and etching process are performed to form circuits and patterns on the surface (the face of processing) of the substrate. In these processes, a developer and a chemical solution for etching are applied to the surface of the substrate. To remove these liquids, cleaning and drying processes are performed in the succeeding steps.

As a substrate processing apparatus that dries and removes a processing liquid such as pure water attached to a substrate in the succeeding steps, there has conventionally been proposed one in which a substrate after being subjected to cleaning is immersed and heated in temperature-controlled pure water, and the substrate is then taken out of there so that the pure water attached to the substrate is dried by the heat stored in the substrate.

Incidentally, the conventional apparatus supplies air of high purity to the atmosphere in a housing (process chamber) when the substrate is taken out of the pure water and then dried. Since air usually contains oxygen, this apparatus would subject an object substrate to drying process in the presence of a relatively large amount of oxygen. If oxygen is present when drying the pure water attached to the substrate, oxygen dissolves in the pure water on the substrate surface and undergoes reactions with silicon (Si) of the substrate material. This causes the problem that damage, being called “water marks,” occurs on the substrate surface, resulting in uneven drying of the substrate.

### SUMMARY OF THE INVENTION

The present invention is directed to a technique of drying a processing liquid attached to a semiconductor substrate or a substrate for liquid crystal after its cleaning process and the like in its manufacturing steps.

According to a first aspect of the present invention, a substrate processing apparatus includes: a process tank, a holding element, a processing liquid supply element, process chamber, an inert gas supply element and a displacement element. The process tank stores a predetermined processing liquid. The holding element holds a substrate in the process tank. The processing liquid supply element supplies a heated processing liquid to the process tank. The process chamber is located above the process tank and performs drying of a substrate. The inert gas supply element supplies an inert gas into the process chamber. The displacement element displaces the substrate held by the holding element from a first position at which a substrate is immersed in a processing liquid to a second position at which the substrate is not immersed in the processing liquid, under condition that an inert gas is supplied into the process chamber by the inert gas supply element after the temperature of the substrate is elevated by the processing liquid heated in the process tank.

This permits drying of a substrate while suppressing the occurrence of water marks.

Preferably, the inert gas supply element has a purge element to discharge the inert gas into the process chamber.

This facilitates to control the flow of the inert gas in the process chamber.

According to a second aspect of the present invention, a substrate processing method includes the steps (a) to (d). The step (a) is to supply a heated processing liquid to a process tank. The step (b) is to immerse a substrate in the process tank in a heated processing liquid. The step (c) is to supply an inert gas into a process chamber. The step (d) is to displace, under condition that an inert gas is supplied into the process chamber after the temperature of a substrate is elevated in the step (b), the substrate from a first position at which a substrate is immersed in a processing liquid in the process tank to a second position at which the substrate is not immersed in the processing liquid.

This permits drying of a substrate while suppressing the occurrence of water marks.

Accordingly, it is an object of the present invention to provide a substrate processing apparatus and a substrate processing method with which it is possible to dry a substrate while suppressing the occurrence of water marks.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram of a substrate processing apparatus according to a first preferred embodiment of the present invention;

FIG. 2 is a block diagram showing the configurations of a nitrogen supply part and blowing mechanism;

FIG. 3 is a block diagram showing the configuration of a hot water unit;

FIG. 4 is a flow chart showing the operation of the substrate processing apparatus of the first preferred embodiment;

FIG. 5 is a flow chart showing the step in which nitrogen gas is supplied by the nitrogen supply part and blowing mechanism;

FIG. 6 is a diagram showing details of the step of supplying hot water in FIG. 4;

FIG. 7 is a diagram showing a substrate processing apparatus according to a second preferred embodiment of the present invention;

FIG. 8 is a flow chart showing the operation of the substrate processing apparatus of the second preferred embodiment; and

FIG. 9 is a flow chart showing the step in which nitrogen gas is supplied by a nitrogen supply part, upper purge pipes and lower purge pipes.

### DESCRIPTION OF THE PREFERRED EMBODIMENTS

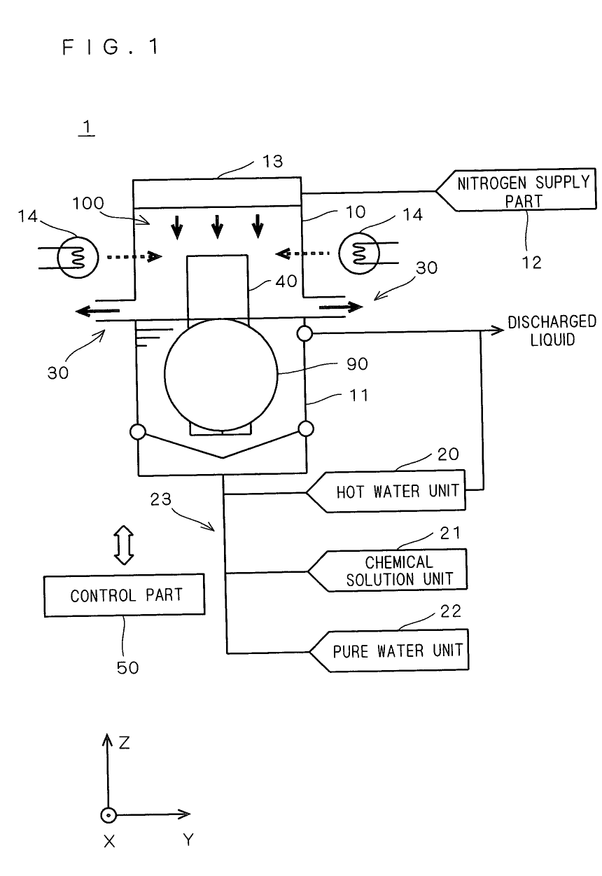

FIG. 1 is a schematic diagram of a substrate processing apparatus 1 according to a first preferred embodiment of the present invention. The substrate processing apparatus 1 of this embodiment takes, as an object substrate 90, a circular semiconductor substrate for manufacturing electronic parts such as LSIs. It should be noted that the substrate processing apparatus 1 is generally susceptible of application to the drying of pure water (processing liquid) attached not only to semiconductor substrates but also rectangular glass substrates for manufacturing a screen panel of a liquid crystal display and various substrates for flat panel display. The following are major components of the substrate processing apparatus 1.

The substrate processing apparatus 1 comprises a chamber 10, quartz tank 11, nitrogen supply part 12, blowing mechanism 13, halogen lamps 14, hot water unit 20, chemical solution unit 21, pure water unit 22, liquid pipe mechanism 23, exhaust mechanism 30, substrate holding mechanism 40 and control part 50. The substrate processing apparatus 1 is configured as an apparatus that, after cleaning a substrate 90 with a chemical solution, performs another cleaning with pure water to remove the chemical solution, and then dries the pure water. As a chemical solution to clean the substrate 90, APM (ammonia-hydrogen peroxide mixture), HPM (hydrochloricacid-hydrogen peroxide mixture, FPM (hydrofluoricacid-hydrogen peroxide mixture), DHF (diluted hydrofluoric acid), O3/DIW (ozone water) are suitably selectively used depending on, for example, the type of a film formed on the substrate 90.

The chamber 10 is composed of a translucent member such as quartz, and a hollow part 100 is formed in the inside of the chamber 10. The hollow part 100 functions as a process chamber by which the peripheral atmosphere of the substrate 90 (the atmosphere of the chamber 10) is separated from the external atmosphere when the substrate processing apparatus 1 performs a predetermined processing (e.g., cleaning process and drying process) of the substrate 90. A lower part of the chamber 10 serves as the quartz tank 11 to store liquid such as hot water, chemical solution or pure water.

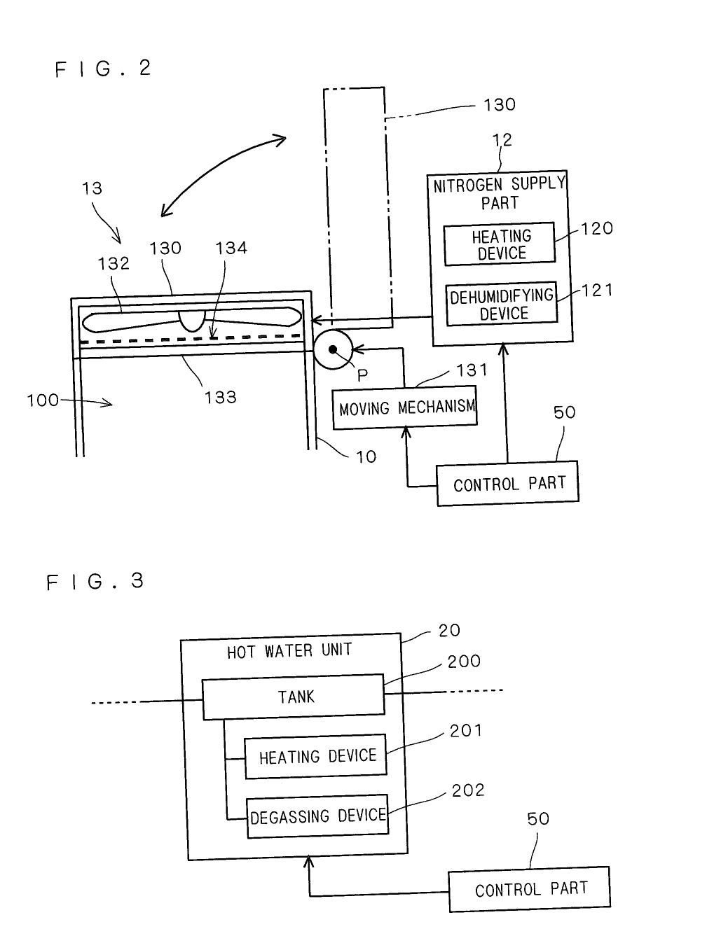

FIG. 2 is a block diagram showing the configuration of the nitrogen supply part 12 and blowing mechanism 13. The nitrogen supply part 12 supplies nitrogen gas via the blowing mechanism 13 to the hollow part 100 in the chamber 10. The nitrogen supply part 12 can bring nitrogen gas into its heated state by use of a heating device 120, and also dehumidify nitrogen gas by use of a dehumidifying device 121.

The control part 50 controls the heating device 120 and dehumidifying device 121 such that the temperature and humidity of nitrogen gas supplied from the nitrogen supply part 12 are adjusted to a predetermined temperature and a predetermined humidity, respectively. That is, the control part 50 and heating device 120 correspond to major inert gas temperature-control element, and the control part 50 and dehumidifying device 121 correspond to major adjusting element. In this preferred embodiment, the predetermined temperature and humidify of supplied nitrogen gas are preset to 85° C. and 6 to 7%, respectively. However, these values are cited merely by way of example and without limitation.

The blowing mechanism 13 has a substantially box-like casing 130, a fan 132 that is rotated by a rotary motor (not shown), and a filter 133 to remove particles and the like from a passing gas (chiefly, nitrogen gas supplied from the nitrogen supply part 12). The blowing mechanism 13 employs the rotary motor to rotate the fan 132 in a predetermined direction, so that the nitrogen gas supplied from the nitrogen supply part 12 is fed to the filter 133 through a slit 134 extending over the entire lower surface of the blowing mechanism 13. The nitrogen gas fed from the nitrogen supply part 12 passes through the filter 133, through which its contaminant such as duct is removed and cleaned. The clean nitrogen gas is then supplied substantially uniformly in the direction of (−Z) over a plane from the upper surface of the chamber 10. The amount of nitrogen gas blown by the blowing mechanism 13 is preferably adjusted to a degree that the liquid surface of hot water in the quartz tank 11 does not wave by the nitrogen gas from the blowing mechanism 13.

Thus, the presence of the filter 133 in the blowing mechanism 13 enables to supply a clean nitrogen gas into the chamber 10 and prevent contaminants such as particles from attaching to the substrate 90 during process. Furthermore, compared to the case of blowing nitrogen gas, for example, from a blowing port disposed at a predetermined position, a down flow occurred in the chamber 10 can be made more uniform by uniformly feeding nitrogen gas from an upper surface of the chamber 10. This avoids uneven drying of the substrate 90.

A moving mechanism 131 rotates the blowing mechanism 13 together with the casing 130 around axis P, so that the blowing mechanism 13 is moved between a position indicated by solid line in FIG. 2 (hereinafter referred to as a “close position”) and a position indicated by dash-double dot line (hereinafter referred to as an “open position”). That is, the blowing mechanism 13 serves as a lid member of the chamber 10. When the blowing mechanism 13 is at its open position, the substrate 90 can be loaded and unloaded with respect to the chamber 10. On the other hand, when the blowing mechanism 13 is at its close position, the internal atmosphere of the chamber 10 and the external atmosphere are separated from each other. It should be noted that the manner that the moving mechanism 131 moves the blowing mechanism 13 is not limited to this. For example, the blowing mechanism 13 may be lifted and lowered in the Z-axis direction, alternatively, the blowing mechanism 13 may be moved so as to slide horizontally.

Returning to FIG. 1, the halogen lamps 14 are disposed in the outside of the chamber 10, and lighted up to emit a predetermined light. Since the chamber 10 is formed by the translucent member, the emitted light goes straight, without being blocked by the chamber 10, in the direction indicated by the arrowed dotted line, and heats the atmosphere of the hollow part 100 (chiefly, composed of nitrogen gas and vapor). That is, the halogen lamps 14 function as a heating element of light radiation type.

In the substrate processing apparatus 1 so configured, the control part 50 controls the light output or emission time of the halogen lamps 14, thereby controlling the temperature of the atmosphere of the chamber 10. Therefore, by maintaining the temperature of the atmosphere in the chamber 10 at a predetermined temperature (in its heated state), a drop in the temperature of the substrate 90 during drying process is avoidable, thereby increasing the efficiency of drying. That is, the control part 50 and halogen lamps 14 chiefly serve as a process chamber temperature control element in the present invention.

Further, with the arrangement that the mechanism of controlling the temperature in the chamber 10 (the halogen lamps 14) is disposed in the outside of the chamber 10, it is possible to facilitate maintenance, for example, when cleaning the inside of the chamber 10, and also simplify the apparatus configuration. Although only two halogen lamps 14 are shown in FIG. 1, the number of the halogen lamps 14 is not limited to this. In an alternative, an infrared heater may be used to configure the heating element of light radiation type that heats the atmosphere in the chamber 10.

FIG. 3 is a block diagram showing the configuration of the hot water unit 20. The hot water unit 20 comprises a tank 200 to temporarily store pure water, a heating device 201 to heat the pure water in the tank 200, and a degassing device 202 to degas the pure water in the tank 200. Under the control of the control part 50, the hot water unit 20 heats pure water to a predetermined temperature by use of the heating device 202, while performing degas process of removing bubbles and the like from the heated pure water by use of the degassing device 202. The degassed heated pure water so obtained (hereinafter referred to simply as a “hot water”) is supplied via the liquid pipe mechanism 23 to the quartz tank 11. In this preferred embodiment, the rate of flow at which the hot water unit 20 supplies a hot water is adjusted to 8 LPM (liter per minute). It is however possible to employ any rate of flow if the hot water in the quartz tank 11 does not wave by the hot water supplied from the hot water unit 20.

Thus, with the configuration that the hot water unit 20 supplies the quartz tank 11 with a pure water heated to a predetermined temperature, the temperature of the substrate 90 can be elevated so as to reserve heat by immersing it in the pure water in the succeeding process. In addition, the degassing device 202 degasses a heated pure water and the hot water unit 20 suppresses the occurrence and residual of bubbles contained in the pure water supplied to the quartz tank 11. This suppresses uneven drying of the substrate 90. In this preferred embodiment the temperature of hot water (the predetermined temperature) is set to 85° C., without limiting to this. Preferably, it is not less than 70° C. and not more than its boiling point. The heating device 201 is preferably a heater that can suppress internal boiling at the time of heating, in order to suppress bubbles to be contained in hot water.

Returning to FIG. 1, the chemical solution unit 21 is a unit that supplies the quartz tank 11 with a chemical solution to clean the surface of the substrate 90. Although in this preferred embodiment there is shown a single chemical solution unit 21, when using a plurality of types of chemical solutions, a chemical solution unit 21 having a similar configuration may be provided for each chemical solution. The pure water unit 22 is a unit that supplies pure water into the quartz tank 11.

The hot water unit 20 is connected to the quartz tank 11 by the liquid pipe mechanism 23. In the liquid pipe mechanism 23, a plurality of solenoid valves (not shown) are disposed properly at predetermined positions. The control part 50 controls these solenoid valves as required, such that a liquid (hot water, chemical solution or pure water) fed to the quartz tank 11 is selected as required. These solenoid valves are also controlled when discharging the liquid stored in the quartz tank 11. In the substrate processing apparatus 1 of this preferred embodiment, a circulatory system is so configured that the hot water unit 20 recovers all the hot water discharged from the quartz tank 11. However, if it is impossible to reuse the used liquid, the circulatory system may be so configured as to discard it.

The exhaust mechanism 30 is a mechanism of sucking the atmosphere in the chamber 10 and exhausting it to the outside of the apparatus through a pipe that is connected from a suction port disposed above the liquid surface of the liquid stored in the quartz tank 11 to a blower (not shown).

With the configuration that the exhaust mechanism 30 exhausts to the exterior an atmosphere of which humidity is increased by evaporation etc, while the nitrogen supply part 12 supplies nitrogen gas of which humidity is adjusted as described, it is possible to eliminate evaporation from the atmosphere in the chamber 10 and lower its humidity. This improves the efficiency of drying of the substrate 90. The amount of suction that the exhaust mechanism 30 sucks the atmosphere in the chamber 10 is preferably adjusted such that the liquid surface of the hot water in the quartz tank 11 is not waved by the suction.

The substrate holding mechanism 40 presses against a lower end of the substrate 90 and functions to hold the substrate 90 such that the surface (the face of processing) of the substrate 90 is substantially parallel to the Z-axis. Although only one substrate 90 is shown in FIG. 1, in the substrate processing apparatus 1 of this preferred embodiment, a plurality of substrates 90 are held coincidently by the substrate holding mechanism 40 in the X-axis direction so that these substrates 90 are substantially parallel to one another, in order to process them at the same time (batch process).

The substrate holding mechanism 40 also lifts and lowers the substrate 90, while holding it, in the Z-axis direction. Specifically, under condition that liquid exceeding a predetermined amount is present in the quartz tank 11, when the substrate holding mechanism 40 is at a first position (the position shown in FIG. 1) in the quartz tank 11, the held substrate 90 is entirely immersed in the liquid within the quartz tank 11. When it is at a second position in the chamber 10, the held substrate 90 is entirely lifted out of the liquid. Therefore, the substrate holding mechanism 40 can immerse the substrate 90 into the liquid in the quartz tank 11 and lift it out of there by changing the relative position between the liquid and the substrate 90 in the quartz tank 11. That is, the substrate holding mechanism 40 chiefly serves as a moving element.

The control part 50 is disposed in the inside of the substrate processing apparatus 1 and connected by a cable (not shown) such that it can send signals to and receive signals from the individual components such as the nitrogen supply part 12, blowing mechanism 13, moving mechanism 131, halogen lamps 14 and substrate holding mechanism 40. The control part 50 also stores a program and various data, and generates a control signal to control these components by suitably processing the various data on the basis of the program. The program and various data are stored in a RAM temporarily storing the information of the program and various data, a ROM (read only memory) and a magnetic disk unit etc.

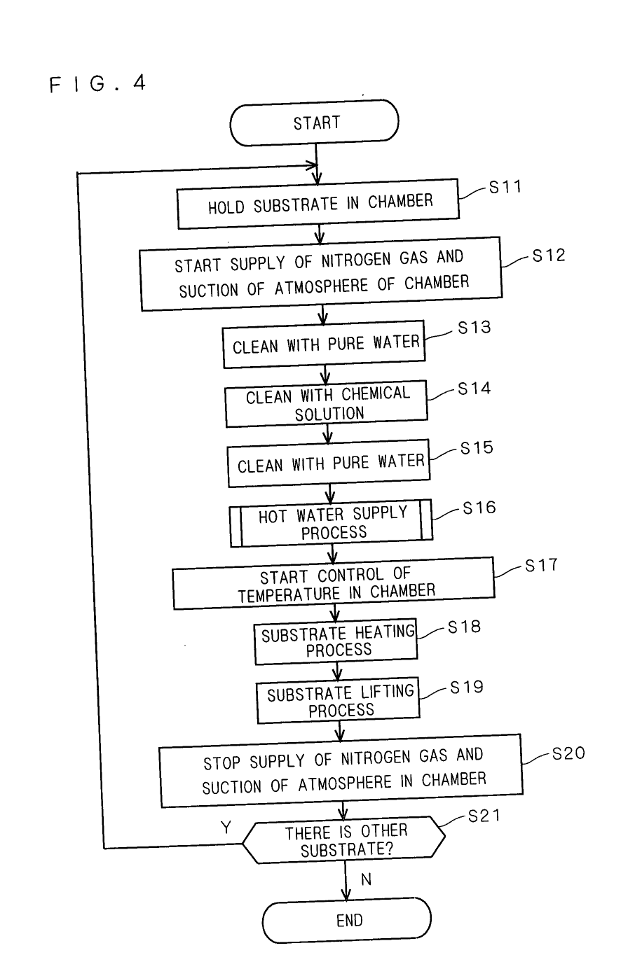

The following is the operation of processing the substrate 90 in the substrate processing apparatus 1. FIG. 4 is a flow chart showing the operation of the substrate processing apparatus 1 in this preferred embodiment. The following control over the operation of the individual components is executed by the control part 50 unless otherwise noted.

In the substrate processing apparatus 1, first, a predetermined initialization, such as setting of the temperatures of nitrogen gas and hot water supplied and the humidity of nitrogen gas, is performed prior to the process shown in FIG. 4. Thereafter, the moving mechanism 131 rotates the blowing mechanism 13 to its open position thereby to open the chamber 10, and a transport apparatus (not shown) transports the substrate 90 into the chamber 10 of the substrate processing apparatus 1.

Subsequently, the substrate holding mechanism 40 moves the transported substrate 90 to a first position, while holding the substrate 90 within the chamber 10 (step S11). In parallel to this operation, the moving mechanism 131 moves the blowing mechanism 13 to its close position, so that the internal atmosphere of the chamber 10 is separated from the external atmosphere and the hollow part 100 of the chamber 10 is brought into its sealed state.

When the chamber 10 is in its sealed state, the nitrogen supply part 12 starts to supply nitrogen gas via the blowing mechanism 13 into the chamber 10, and the exhaust mechanism 30 starts to suck the atmosphere of the chamber 10 (step S12).

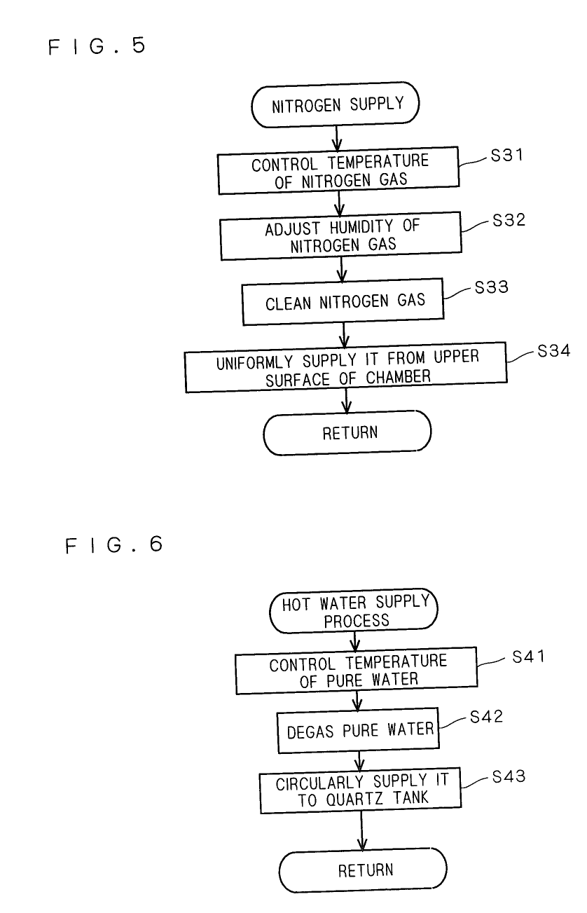

FIG. 5 is a flow chart showing the step in which nitrogen gas is supplied by the nitrogen supply part 12 and blowing mechanism 13. In the basis of a control signal from the control part 50, the nitrogen supply part 12 employs the heating device 120 to control nitrogen gas so as to be in a heated state of 85° C. (step S31), and employs the dehumidifying device 121 to adjust the humidify of nitrogen gas to 40% (step S32).

While the nitrogen gas of which temperature and humidity are so adjusted is cleaned by feeding it in a predetermined direction (the (−Z) direction in FIG. 1) so as to pass through the filter 133 (step S33) by use of the fan 132 of the blowing mechanism 13, it is uniformly supplied from an upper surface of the chamber 10 (step S34). Since the suction of the atmosphere of the chamber 10 is already started at the same time in step S12, the external atmosphere (chiefly air) taken in the chamber 10 by loading and unloading of the substrate 90 is exhausted and replaced with nitrogen gas.

In this preferred embodiment, the processes shown in FIG. 5 (steps S31 through S34) are continuously executed while supplying nitrogen gas. Alternatively, the processes of steps S31 and S32 may be started prior to the process of starting supply of nitrogen gas (step S12), or these adjustments may be started in proper timed relation with the start of drying process to be described later. That is, the nitrogen gas supplied during the drying process of the substrate 90 need only be subjected to adjustments of its temperature and humidity.

Next, the substrate processing apparatus 1 performs cleaning with pure water with respect to the substrate 90 loaded in the chamber 10 (step S13). Specifically, the control part 50 controls properly the solenoid valves of the liquid pipe mechanism 23, so that a predetermined amount of pure water is supplied from the pure water unit 22 to the quartz tank 11. Thereby, the substrate 90 at the first position in the chamber 10 can be immersed in pure water and cleaned with pure water. This cleaning process with pure water is completed on termination of the discharge of pure water in the quartz tank 11. The discharge of pure water in the quartz tank 11 is started when a predetermined period of time is elapsed and the solenoid valves of the liquid pipe mechanism 23 are opened by the control part 50.

Subsequently, the substrate processing apparatus 1 performs cleaning of the substrate 90 with a chemical solution (step S14). Also in this case, the control part 50 controls properly the solenoid valves of the liquid pipe mechanism 23, so that a predetermined amount of the chemical solution is supplied from the chemical solution unit 21 to the quartz tank 11. Thereby, the substrate 90 at the first position in the chamber 10 can be immersed in the chemical solution and cleaned with the chemical solution. Like the cleaning with pure water in step S13, the cleaning with the chemical solution is completed on termination of the discharge of the chemical solution in the quartz tank 11. The discharge of the chemical solution in the quartz tank 11 is started when a predetermined period of time is elapsed and the solenoid valves of the liquid pipe mechanism 23 are opened by the control part 50. Then, another cleaning with pure water similar to that in step S13 is performed in the substrate processing apparatus 1 (step S15), so that the chemical solution attached to the substrate 90 is cleaned and removed by the pure water.

In the case where a cleaning device to perform cleaning with a chemical solution with respect to the film formed on the substrate 90 is placed separately from a drying device to perform drying after the cleaning, the substrate that is wet after the cleaning with the cleaning device would be transported to the drying device. If the wet substrate is transported, the liquid attached to the substrate may attach to other mechanisms (the transportation mechanism etc.) during the transportation, thus causing particles. There is also the problem that the substrate is partially dried during the transportation, resulting in uneven drying. However, the substrate processing apparatus 1 of this preferred embodiment can perform cleaning with a chemical solution in the same chamber 10, prior to the drying process to be described later. It is therefore unnecessary to transport the substrate 90 in its wet state. This is effective in preventing the above-mentioned problem.

At the completion of the cleaning and removal of the chemical solution attached to the substrate 90 by performing the cleaning with pure water in step S15, the substrate processing apparatus 1 executes a hot water supply process (step S16), and the control part 50 controls the halogen lamps 14 to start control of the temperature in the chamber 10 (step S17).

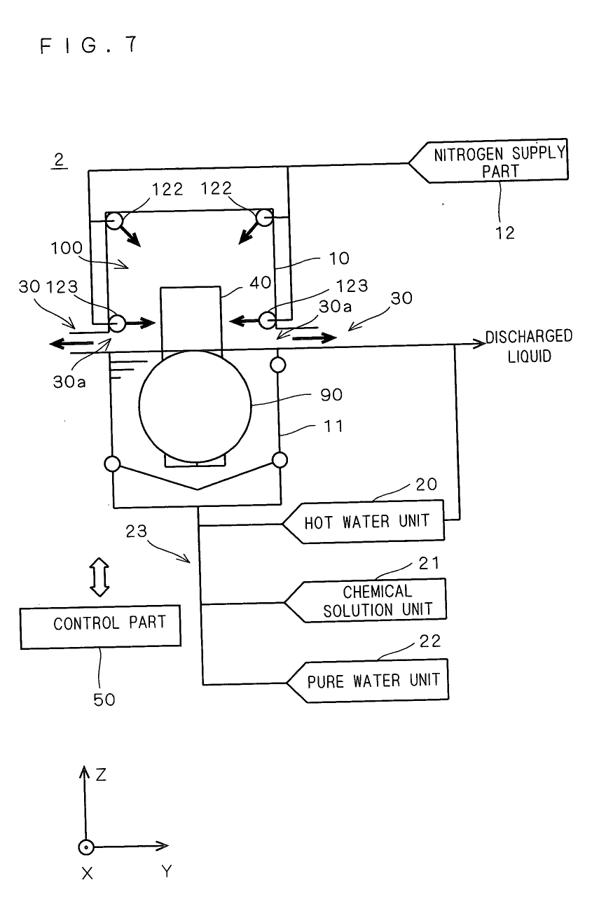

FIG. 6 is a diagram showing details of the hot water supply process in FIG. 4. In the hot water supply process, first, the heating device 201 adjusts the temperature of pure water in the tank 200 to 85° C. (step S41). Then, the degassing device 202 degasses the pure water in the tank 200 (step S42), and circularly supplies hot water to the quartz tank 11 through the liquid pipe mechanism 23 (step S43). The term “to circularly supply” means that the hot water in the quartz tank 11 is recovered into the hot water unit 20 at the same time that hot water is supplied from the hot water unit 20, to thereby circulate hot water between the hot water unit 20 and quartz tank 11.

Thus, the temperature of the hot water in the quartz tank 11 can be maintained substantially constant by the hot water unit 20 circularly supplying hot water adjusted to a predetermined temperature. If the quartz tank 11 is provided with the same configuration as the heating device 201 and dehumidifying device 202, it is unnecessary to circularly supply hot water. In such a case, the hot water unit 20 has the same configuration as the pure water unit 22. Therefore, a single unit may be used as the hot unit 20 and pure water unit 22.

When hot water is supplied to the quartz tank 11, the substrate 90 at the first position is immersed in the hot water and a substrate heating process is started (step S18). In the substrate heating process, the hot water transfers heat to the substrate 90 and the heat accumulate in the substrate 90. Since the temperature of the hot water in the quartz tank 11 is maintained substantially constant by the control part 50 and heating device 201 as described above, the temperature of the hot water is hardly lowered. This permits the substrate processing apparatus 1 to efficiently perform heating process of the substrate 90.

The control part 50 detects the temperature of the substrate 90 in the heating process by use of a thermo-sensor etc., and starts to lift the substrate 90 when the temperature of the substrate 90 is approximately the same as the hot water (step S19). Alternatively, the period of time from that the substrate 90 is immersed in hot water to that it has approximately the same temperature as the hot water may be previously measured in order to start the lifting of the substrate 90 in proper timed relation with an elapse of the period of time so obtained.

Because hot water (pure water) attached to part of the surface of the substrate 90 that is lifted from hot water is placed in the atmosphere of the chamber 10 (nitrogen gas having properly adjusted temperature and humidity) and because the substrate 90 accumulates heat, this hot water evaporates quickly to facilitate the drying of the substrate 90. That is, the lifting process of the substrate 90 in step S19 corresponds to the process of drying the pure water attached to the substrate 90. The operation of lifting the substrate 90 is achieved by the control part 50 controlling the substrate holding mechanism 40 such that the substrate 90 is moved to a second position.

In this manner, after elevating the temperature of the substrate 90 at the first position, the substrate holding mechanism 40 can start to move the substrate 90 to the second position, thus enabling to start drying after the substrate 90 gets warm enough (accumulates heat). In this preferred embodiment, a moving speed (lifting speed) at which the substrate holding mechanism 40 moves the substrate 90 is controlled to be 1 mm/sec by the control part 50. It is however desirable to set the speed properly depending on the features of the substrate 90 such as shape and size, and the temperature of hot water.

At the point that the substrate 90 has been moved to the second position and a predetermined period of time has elapsed since the substrate 90 was entirely lifted from hot water, the substrate processing apparatus 1 regards that the drying of the substrate 90 is completed and stops the supply of nitrogen gas and the suction of the atmosphere of the chamber 10 (step S20). In this occasion, the circulative supply of hot water from the hot water unit 20 may also be stopped at the same time.

Subsequently, the moving mechanism 131 moves the blowing mechanism 13 to its open position, and a transport mechanism (not shown) receives the substrate 90 held by the substrate holding mechanism 40 and then unloads it from the chamber 10.

Further, the substrate processing apparatus 1 judges whether there is other substrate 90 to be processed (step S21), and repeats the process from step S11 if there is a substrate 90, whereas terminates the process if not.

Through the foregoing steps, the substrate processing apparatus 1 of the first preferred embodiment performs the drying process of the substrate 90, while supplying nitrogen gas into the chamber 10 by the nitrogen supply part 12 and blowing mechanism 13. This enables to dry the substrate 90 in a lower oxygen atmosphere than the conventional apparatus. It is therefore possible to suppress the occurrence of water marks on the surface of the substrate 90, thereby avoiding uneven drying of the substrate 90.

In addition, during the drying process of the substrate 90 (during the lifting process of the substrate 90), the blow amount of nitrogen gas, the suction amount of atmosphere in the chamber 10 and the supply amount of hot water are controlled so as not to wave the liquid surface of hot water in the quartz tank 11. It is therefore avoidable that any hot water attaches again to the surface of the substrate 90 after being subjected to the drying process.

In the first preferred embodiment, the blowing mechanism 13 blows the nitrogen gas supplied from the nitrogen supply part 12 into the chamber 10. However, it should be noted that the mechanism of feeding nitrogen gas into the chamber 10 is not limited to this. In an alternative, the so-called purge pipe may be used.

FIG. 7 is a diagram showing a substrate processing apparatus 2 in a second preferred embodiment, which is configured in accordance with this alternative. In the substrate processing apparatus 2 of the second preferred embodiment, components identical to that in the substrate processing apparatus 1 of the first preferred embodiment are identified by the same reference numerals. For convenience, some description will be omitted here.

The substrate processing apparatus 2 is provided with upper purge pipes 122 and lower purge pipes 123. In FIG. 7, halogen lamps 14 and moving mechanism 131 are omitted. The moving mechanism 131 in the first preferred embodiment rotates the blowing mechanism 13 to open and close the chamber 10. Whereas a moving mechanism 131 in the second preferred embodiment is configured as a mechanism to rotate only a casing 130. An exhaust mechanism 30 is connected in communication to a chamber 10 through an exhaust port 30a disposed in the chamber 10.

The upper and lower purge pipes 122 and 123 are tubular members extending in the X-axis direction, and having a slit (not shown) through which nitrogen gas is blown to a predetermined position on a cylindrical side surface. The upper and lower purge pipes 122 and 123 are connected in communication to a nitrogen supply part 12 through a pipe, and function to discharge the nitrogen gas supplied from the nitrogen supply part 12 such that it is distributed substantially uniformly in the chamber 10. In the substrate processing apparatus 2, the direction of flow of nitrogen gas supplied to the chamber 10 is prescribed by the locations of the upper and lower purge pipes 122 and 123 and the position of the above-mentioned slits disposed therein. That is, the substrate processing apparatus 2 can control easily the flow of nitrogen gas in the chamber 10. In an alternative, instead of the above-mentioned slits, nozzles may be arranged at predetermined intervals in the upper and lower purge pipes 122 and 123. It should be noted that the position and number of purge pipes are not limited to that described in this preferred embodiment.

A pair of upper purge pipes 122 are arranged above the chamber 10 and, as shown in FIG. 7, slits are provided such that nitrogen gas is blown downwardly. Therefore, the upper purge pipes 122 mainly form a down flow of nitrogen gas in the chamber 10.

A pair of lower purge pipes 123 are arranged in the vicinity of above the exhaust ports 30a in a lower part of the chamber 10, and slits are provided such a position that nitrogen gas is blown substantially horizontally. That is, the direction in which the lower purge pipes 123 blow nitrogen gas is substantially parallel to the liquid surface of liquid stored in the quartz tank 11. In the substrate processing apparatus 2, the lower purge pipes 123 are so arranged that a so-called air curtain is formed in a direction substantially parallel to the liquid surface in the chamber 10. The nitrogen gas fed from the lower purge pipes 123 is directly blown against the substrate 90 that is lifted from the liquid surface.

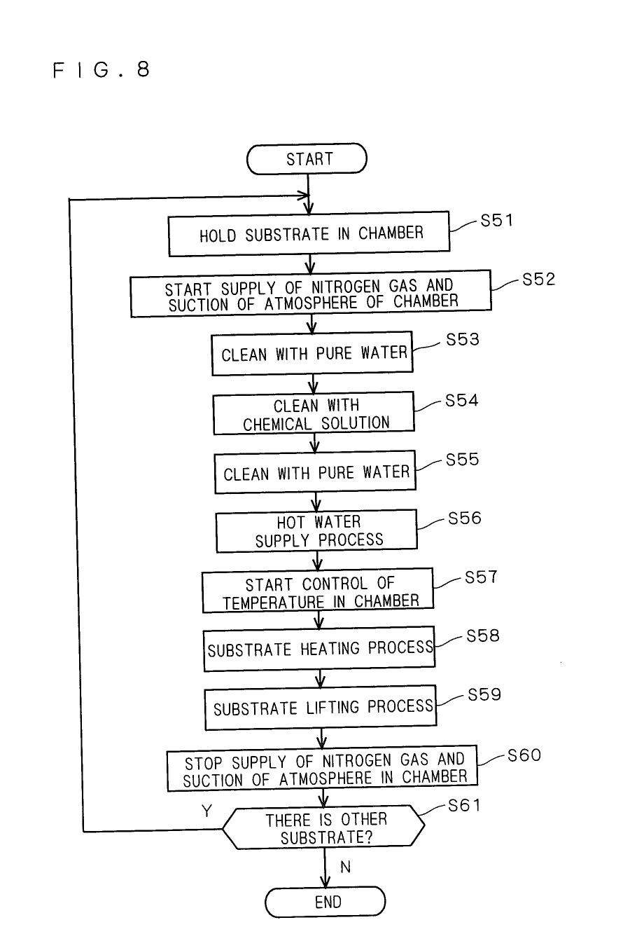

The following is the operation of the substrate processing apparatus 2 in the second preferred embodiment. FIG. 8 is a flow chart showing the operation of the substrate processing apparatus 2. Since the operation of the substrate processing apparatus 2 is basically similar to that of the substrate processing apparatus 1 in the first preferred embodiment, and some description will be omitted hereinafter.

First, the substrate processing apparatus 2 executes a predetermined initialization such as setting of the temperatures of nitrogen gas and hot water supplied and the humidity of nitrogen gas. Thereafter, the moving mechanism 131 rotates the casing 130 to its open position so that the chamber 10 is opened and a transport apparatus (not shown) transports the substrate 90 into the chamber 10 in the substrate processing apparatus 2.

Subsequently, the substrate holding mechanism 40 holds and moves the substrate 90 to the first position (step S51). In parallel to this operation, the moving mechanism 131 moves the casing 130 to its close position, so that a hollow part 100 of the chamber 10 is brought into its sealed state.

At the point that the chamber 10 is in its sealed state, the nitrogen supply part 12 starts to supply nitrogen gas through the upper purge pipes 122 and lower purge pipes 123. The exhaust mechanism 30 also starts to suck the atmosphere of the chamber 10 through the exhaust ports 30a (step S52).

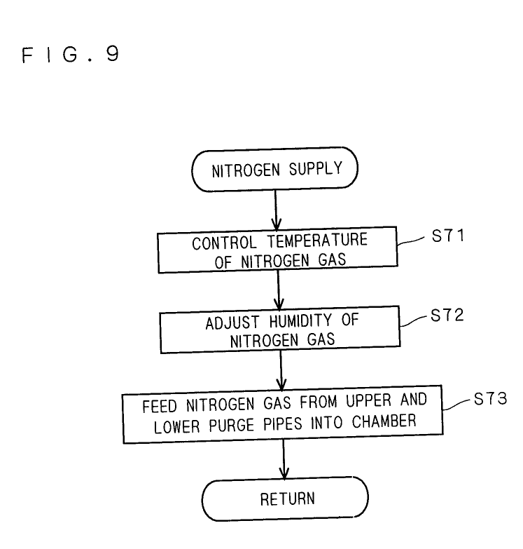

FIG. 9 is a flow chart showing the process of supplying nitrogen gas by the nitrogen supply part 12 and upper and lower purge pipes 122 and 123. The nitrogen supply part 12 employs a heating device 120 and dehumidifying device 121 to adjust the temperature and humidity of nitrogen gas supplied, respectively (step S71, step S72). Then, the nitrogen supply part 12 discharges nitrogen gas so adjusted through the upper and lower purge pipes 122 and 123 into the chamber 10 (step S73).

Here, the nitrogen gas is blown out of the upper purge pipes 122, and the exhaust mechanism 30 exhausts the atmosphere through the exhaust ports 30a, thereby forming a down flow in the chamber 10 as described above. Accordingly, the external atmosphere (chiefly air) that is taken in the chamber 10 by opening the chamber 10 is quickly exhausted to the outside of the chamber 10, so that the atmosphere of the chamber 10 is efficiently replaced with nitrogen gas. This permits the substrate processing apparatus 2 to perform the following processes in an atmosphere of low oxygen concentration, thereby suppressing the occurrence of water marks.

Subsequently, the substrate processing apparatus 2 performs the same processes as in step S13 through step S17 in the substrate processing apparatus 1. Specifically, it performs cleaning with pure water with respect to the substrate 90 loaded in the chamber 10 (step S53), and cleaning with a chemical solution with respect to the substrate 90 (step S54), followed by cleaning with pure water in order to remove the chemical solution (step S55). Further, the substrate processing apparatus 2 executes a hot water supply process (step S56), and controls the halogen lamps 14 to start control of the temperature in the chamber 10 (step S57).

As hot water is supplied into the quartz tank 11, the pure water in the quartz tank 11 is gradually replaced with hot water. In this manner, the substrate 90 at the first position is immersed in the hot water to start a substrate heating process (step S58).

At this point, the lower purge pipes 123 form an air curtain in the chamber 10 in the substrate processing apparatus 2, to thereby suppress vapor diffusing upward which is generated from the liquid surface by vaporization. As the result, the vapor generated from the liquid surface remains below the air curtain and then exhausted quickly to the exterior of the chamber 10 by the exhaust mechanism 30. This permits the substrate processing apparatus 2 to suppress an increase in the humidity of the hollow part 100.

The substrate processing apparatus 2 starts to lift the substrate 90 at the same timing as in the substrate processing apparatus 1 of the first preferred embodiment (step S59). Since hot water attached to part of the surface of the substrate 90 which is lifted from hot water is placed in the atmosphere of the chamber 10 and the substrate 90 accumulates heat, this hot water evaporates quickly.

In the substrate processing apparatus 2 of the second preferred embodiment, the pure water attached to the substrate 90 can be dried efficiently because the lower purge pipes 123 blow nitrogen gas directly to the substrate 90. Further, the formation of an air curtain in the chamber 10 prevents that vapor generated from the liquid surface diffuses into the chamber 10, to thereby suppress an increase in the humidity of the hollow part 100. It is therefore possible to suppress dew condensation of pure water with respect to the substrate 90 lifted from hot water. Furthermore, the air curtain suppresses that the nitrogen gas blown downward from the upper purge pipes 122 directly strikes hot water, thereby suppressing the liquid surface of hot water from waving.

At the point that the substrate 90 has been moved to the second position by the lifting process of the substrate 90 and a predetermined period of time has elapsed since the substrate 90 was entirely lifted from hot water, the substrate processing apparatus 2 regards that the drying of the substrate 90 is completed and stops the supply of nitrogen gas and the suction of the atmosphere in the chamber 10 (step S60).

Subsequently, the moving mechanism 131 moves the blowing mechanism 13 to its open position so that the chamber 10 is opened. Then, a transport mechanism (not shown) receives the substrate 90 held by the substrate holding mechanism 40 and then unloads it from the chamber 10.

Further, the substrate processing apparatus 2 judges whether there is other substrate 90 to be processed (step S61), and repeats the process from step S51 if there is other substrate 90, whereas terminates the process if not.

Thus, the substrate processing apparatus 2 of the second preferred embodiment also provides the same effect as in the substrate processing apparatus 1 of the first preferred embodiment, and also provides the following advantages.

Firstly, efficient drying process is executable because the flow of nitrogen gas in the chamber 10 can easily be controlled as required, by using the purge pipes as a mechanism of discharging nitrogen gas in the chamber 10.

Secondly, the pure water attached to the substrate 90 can efficiently be dried because the lower purge pipes 123 directly blow nitrogen gas against the substrate 90.

Thirdly, the dew condensation with respect to the substrate 90 lifted from hot water can be suppressed because the formation of an air curtain in the chamber 10 prevents that vapor generated from the liquid surface diffuses into the chamber 10, thereby suppressing an increase in the humidity of the hollow part 100.

Lastly, the air curtain suppresses that the nitrogen gas blown downwardly from the upper purge pipes 122 directly strikes the liquid surface of hot water thereby to suppress the liquid surface of hot water from waving. This allows for efficient drying of the substrate 90 during the lifting process.

The foregoing description has been made that in the substrate processing apparatus 2 the nitrogen gas blown from both of the upper and lower purge pipes 122 and 123 is heated by the heating device 120. In an alternative, only nitrogen gas blown from the lower purge pipes 123 may be heated. This reduces the heating capacity of the heating device 120.

Although in step S52, the upper purge pipes 122 and lower purge pipes 123 start to blow nitrogen gas at the same time, they may blow nitrogen gas at different timings. Alternatively, during the time that the atmosphere of the chamber 10 is chiefly replaced with nitrogen gas, only the upper purge pipes 122 blow nitrogen gas to form a down flow and the lower purge pipes 123 blow nitrogen gas to form an air curtain, after the hot water supply process in step S56 is started and before the occurrence of vapor from the liquid surface is increased.

In the foregoing preferred embodiments, when hot water, chemical solution or pure water is supplied from their respective units to the quartz tank 11, the pipe of the liquid pipe mechanism 23 is partially shared. In an alternative, the individual units may be provided with every discrete pipe.

In the foregoing preferred embodiments, the relative position between the hot water and the substrate 90 in the quartz tank 11 is changed by the substrate holding mechanism 40 lifting the substrate 90 from the hot water. The substrate 90 is then dried while being exposed to the atmosphere of the chamber 10. However, the method of changing the above-mentioned relative position such that the substrate 90 is exposed to the atmosphere of the chamber 10 should not be limited to this. For example, the hot water in the quartz tank 11 may be discharged by a liquid discharge mechanism (not shown), so that the amount of hot water stored in the quartz tank 11 is gradually decreased.

It should be noted that gas supplied into the chamber 10 during the drying process is not limited to nitrogen gas. For example, a variety of inert gases containing no oxygen such as neon gas and argon gas may be supplied.

The substrate processing apparatuses 1 and 2 of the first and second preferred embodiments are provided with the chemical solution unit 21 and configured as an apparatus that can perform the cleaning with a chemical solution with respect to the substrate 90 (step S14). Alternatively, other apparatus may perform such a process and the substrate processing apparatus of the present invention may be so configured as only to dry pure water (processing liquid) attached to the substrate 90.

While the invention has been shown and described in detail, the foregoing description is in all aspects illustrative and not restrictive. It is therefore understood that numerous modifications and variations can be devised without departing from the scope of the invention.

What is claimed is:

1. A substrate processing apparatus performing a predetermined process to a substrate, comprising:
a process tank to store a predetermined processing liquid;
a holding element to hold a substrate in said process tank;
a processing liquid supply element to supply a heated processing liquid to said process tank;
a process chamber to perform drying of a substrate, said process chamber being disposed above said process tank;
an inert gas supply element to supply an inert gas into said process chamber; and
a displacement element to displace a substrate held by said holding element from a first position at which a substrate is immersed in a processing liquid to a second position at which the substrate is not immersed in the processing liquid, under condition that said inert gas supply element supplies an inert gas into said process chamber after the temperature of the substrate is elevated by a processing liquid heated in said process tank.

2. The substrate processing apparatus according to claim 1 further comprising:
a process chamber temperature control element to control the atmosphere of said process chamber so as to be in a heated state.

3. The substrate processing apparatus according to claim 2 wherein
said process chamber includes a translucent member, and
said process chamber temperature control element is a heating element of light radiation type and disposed in the exterior of said process chamber.

4. The substrate processing apparatus according to claim 1 further comprising:
an exhaust element to exhaust the atmosphere of said process chamber under condition that a substrate held by said holding element is displaced from a first position to a second position by said displacement element.

5. The substrate processing apparatus according to claim 1 wherein
said processing liquid supply element supplies a chemical solution to said process tank.

6. The substrate processing apparatus according to claim 1 wherein said processing liquid supply element supplies said process tank with a pure water heated to not less than 70° C., as said predetermined processing liquid.

7. The substrate processing apparatus according to claim 1 wherein
said processing liquid supply element includes a bubble suppressing element to suppress bubbles contained in a processing liquid before it is supplied to said process tank.

8. The substrate processing apparatus according to claim 1 wherein
said inert gas supply element includes a filter element to clean said inert gas supplied into said process chamber, said inert gas supply element supplying said inert gas from an upper surface of said process chamber through said filter element.

9. The substrate processing apparatus according to claim 1 wherein
said inert gas supply element includes a purge element to discharge said inert gas into said process chamber.

10. The substrate processing apparatus according to claim 9 wherein
said exhaust element includes an exhaust port provided in said process chamber, said exhaust port being located in the vicinity of the liquid surface of said predetermined processing liquid stored in said process tank, and
said purge element is located in the vicinity of above said exhaust port.

11. The substrate processing apparatus according to claim 9 wherein
said purge element discharges said inert gas in a direction substantially parallel to the liquid surface of said predetermined processing liquid.

12. The substrate processing apparatus according to claim 1 wherein
said inert gas supply element includes an adjusting element to adjust the humidity of an inert gas supplied into said process chamber.

13. The substrate processing apparatus according to claim 1 wherein
said inert gas supply element includes an inert gas temperature control element to control an inert gas supplied into said process chamber so as to be in a heated state.

14. The substrate processing apparatus according to claim 1 wherein
said holding element holds a substrate such that the face of processing of the substrate is substantially parallel to a vertical direction in said process chamber.

15. A substrate processing method of performing a predetermined process to a substrate, comprising the steps of:
(a) supplying a heated processing liquid to a process tank;
(b) immersing a substrate in said process tank in a heated processing liquid;
(c) supplying an inert gas into a process chamber; and
(d) displacing, under condition that an inert gas is supplied into said process chamber after the temperature of a substrate is elevated in said step (b), the substrate from a first position at which a substrate is immersed in a processing liquid in said process tank to a second position at which the substrate is not immersed in the processing liquid.

16. The substrate processing method according to claim 15, further comprising the step of:
(e) controlling the atmosphere in said process chamber so as to be in a heated state.

17. The substrate processing method according to claim 15, further comprising the step of:
(f) exhausting the atmosphere of said process chamber under condition that a substrate is displaced from said first position to said second position in said step (d).

18. The substrate processing method according to claim 15 wherein
said step (a) supplies said process tank with pure water heated to not less than 70° C., as said heated processing liquid.

19. The substrate processing method according to claim 15 wherein
said step (a) includes the step of:
(a-1) suppressing bubbles contained in said predetermined processing liquid before supping it to said process tank.

20. The substrate processing method according to claim 15 wherein
said step (c) includes the step of:
(c-1) cleaning an inert gas supplied to said process chamber and supplying said inert gas from an upper surface of said process chamber.

21. The substrate processing method according to claim 15 wherein
said step (c) includes discharging said inert gas into said process chamber by a purge element.

22. The substrate processing method according to claim 21 wherein
said step (c) includes discharging said inert gas in a direction substantially parallel to the liquid surface of said predetermined processing liquid.

23. The substrate processing method according to claim 15 wherein
said step (c) includes the step of:
(c-2) adjusting the humidify of an inert gas supplied to said process chamber.

24. The substrate processing method according to claim 15 wherein
said step (c) includes the step of:
(c-3) controlling an inert gas supplied to said process chamber so as to be in a heated state.
